(19) United States
(12) Patent Application Publication
(10) Pub. No.: US 2010/0270574 A1
(43) Pub. Date: Oct. 28, 2010

(54) Silicone coated light-emitting diode

(75) Inventors: Robert J. Nolan, Salisbury, NC (US); Jeffery D. Harman, SR., Salisbury, NC (US)

Correspondence Address: K&L Gates LLP, 214 N. TRYON STREET, HEARST TOWER, 47TH FLOOR, CHARLOTTE, NC, 28202, US

(73) Assignee: Shat-R-Shield, Inc., Salisbury, NC (US)

(21) Appl. No.: 12/799,238

(22) Filed: Apr. 21, 2010

Related U.S. Application Data
(60) Provisional application No. 61/214,323, filed on Apr. 22, 2009.

(51) Int. Cl. H01L 33/44; H01L 33/00

(52) U.S. Cl. 257/98; 438/29; 257/E33.061

(57) ABSTRACT

A silicone coated light-emitting diode and the method for making the silicone coated light-emitting diode.

### CROSS-REFERENCE TO RELATED APPLICATIONS

This application claims the benefit of U.S. provisional patent application 61/214,323, filed Apr. 22, 2009, herein incorporated by reference.

### FIELD OF THE INVENTION

The present invention relates to light-emitting diodes.

### BACKGROUND OF THE INVENTION

A light-emitting diode, also referred to as a LED, is an electronic light source. LEDs have many known advantages over traditional light sources including smaller size, longer lifetime, lower energy consumption, and higher efficiency as measured by its light output per unit power input. The average length of life of a typical LED is estimated to be about 100,000 hours. In order to protect the circuitry and electronic components of a LED for such a duration, exposure to outside forces should be a critical consideration. However, until now there has not been a solution that effectively addresses or solves the problems associated with a LED's exposure to environmental factors such as moisture yet still provides for the known advantages and performance characteristics associated with a LED.

### SUMMARY OF THE INVENTION

The present invention relates to a coated light-emitting diode and the method for making the coated light-emitting diode.

The method of making a coated light-emitting diode in accordance with the present invention comprises providing a light-emitting diode having a surface, and spray coating the surface of the light-emitting diode with a liquid coating composition comprising silicone.

The coated light-emitting diode in accordance with the present invention has a coated surface, and the coating of the coated light-emitting diode comprises silicone.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### DETAILED DESCRIPTION OF THE INVENTION

The following detailed description of the embodiment(s) is merely exemplary in nature and is in no way intended to limit the invention, its application, or uses.

The present invention relates to a coated light-emitting diode and the method for making the coated LED. The coated LED of the present invention provides a solution to the problems associated with moisture management while minimizing yellowing and loss of lumen output of the LED.

In accordance with the present invention, a coating is applied to the LED to act as a protective barrier layer to the LED. As a barrier layer, the coating mitigates or prevents moisture and, hence, reduces or eliminates degradation of the LED due to moisture or other degrading elements. The coating after having been applied to the LED forms a clear or translucent film that minimizes yellowing and the loss of lumen output generated by the LED.

The method of the present invention is suitable for use with numerous types, sizes, and shapes of LEDs. There are any number of known types and sizes of LEDs that are commercially available to one of ordinary skill in the art and that could be readily used in accordance with the method of the present invention.

The method of the present invention comprises providing an LED having an exposed surface to be coated. There are numerous commercial suppliers of LEDs. Examples of such commercial suppliers are Seoul Semiconductor, Cree, Inc., Lumileds and Osram Sylvania. An LED suitable for use in the present invention is a white, colored, or multi-colored LED. The particular. LED selected often depends upon the desired end-use application. However, one of ordinary skill in the art would know which LEDs are suitable for a given end-use application. The method of the present invention is particularly suitable for any outdoor end-use application or any non-conditioned environment. For example, outdoor signage and street lights are non-limiting examples of potential end-use applications for the coated LED of the present invention.

The method of the present invention comprises coating an exposed surface or a portion of an exposed surface of a LED with a coating composition. The coating acts as a barrier layer and conforms to the shape of the LED. Based upon the spraying technology discussed herein, it is not necessary to mask the electrodes (leads). The spraying technology has computer programmable capabilities that allow the coating to selectively move around the leads. Prior to coating the LED, however, it is still possible for the LED to be prepared by masking the electrodes (leads), such that when the LED is wired to a light there is a clean lead at which to attach the wiring.

The coating composition of the present invention comprises silicone. The coating composition of the present invention is in the form of a liquid.

The coating composition of the present invention preferably comprises at least 60 weight percent (wt %) of a silicone. For example, the composition may comprise at least 99 wt % of a silicone. The coating for use in the present invention may further comprise other components such as from 0 to 40 wt % of diisopropoxy di(ethoxyacetoacetyl) titanate, alkoxysilane reaction product, methyl alcohol, or a combination thereof.

Examples of suitable commercially available silicones include, but are not limited to, silicones available from Humiseal, silicones available from Dow Corning such as DOW CORNING® 3-1953 Conformal Coating, and silicones available from Shin Etsu such as X-832-407.

In the method of the present invention, the coating composition is applied by spraying the liquid silicone coating composition onto the exposed surface or a portion of an exposed surface of the LED to coat the LED. The LED is preferably sprayed at ambient conditions. The LED may be sprayed in a spray booth.

The liquid coating composition is preferably sprayed with an air-assisted airless spray system or a bead and air swirl system. A bead and air swirl system applies the silicone coating as a bead and uses air to create a swirl pattern. The latter system is desirable because of its improvement in transfer efficiency and because such a system provides good coverage with little bounce back of the liquid spray. The silicone coating can be sprayed at ambient conditions. The LED shape is programmed into the spray system with the exact area to coat and the area to leave uncoated. Since spray time is based upon the size and shape of the LED, spray times vary up to about twenty seconds. The thickness of the silicone coating is typically in a range of 5 to 8 mils. Examples of commercially available spray systems include, but are not limited to, Asymtek of Nordson Corporation or systems available from PVA.

Other advantages of the system of the present invention include the capability to apply small amounts of silicone in small selective areas. This is accomplished using the aforementioned computer programming capabilities to select the appropriate valve to dispense the liquid into the desired area.

The LED is placed on a transfer belt and sprayed at ambient conditions in a spray booth. The LED is transported via the belt to a curing oven.

Subsequent to being spray coated, the coated LED is cured. Curing typically occurs in a forced air oven for curing for a silicone coating. The LED is exposed to 350 degrees F. for approximately 10 to 15 minutes. The system is designed around the use of hot air being impinged on the LED. As the LED exits the curing oven, the LED is cooled in ambient conditions. The masking on the electrodes (leads) is removed.

The production rate of coated LEDs varies depending upon the size and shape of the LED as well as its end-use application. For example, the production rate varies depending upon whether there is linear or down lighting. Based upon the end-use application, typical production speeds may vary between 90 to 150 parts per hour.

As indicated herein, a silicone composition spray coated on the LED provides a transparent moisture management system that lasts the length of life for the LED yet minimized yellowing and loss of lumen output. The liquid spray coating method is particularly desirable as compared to other coating methods that might otherwise be available. For example, it was determined from experimentation that it was difficult to get an even coating as well as a smooth coating with a powder spray. For example, the powder coatings cured with a convection oven were grainy and the LED detached from its base due to the curing temperature, thus creating aesthetic and performance failures.

Advantages of the silicone coating composition and method of the present invention include, but are not limited to, the silicone composition does not deteriorate with ultraviolent (UV) light, silicone remains flexible at higher temperatures, and the silicone composition yellows less than other coating, compositions.

### EXAMPLES

Sample LED boards of various shapes and sizes were spray coated with liquid silicone. Two trials were run. One trial used the Asymtek SL-940E spray system. The other trial used the PVA 2000 Selective Coating System. Each trial tested LED boards spray coated with a silicone product manufactured by Dow Corning, DOW CORNING® 3-1953 Commercial Conformal Coating, and LED boards coated with a liquid silicone available from Shin Etsu, X-832-407.

LED boards were independently tested for environmental and electrical testing as well as Lumen maintenance. Lumen maintenance refers to the amount of light lost due to the coating process. All tests were conducted by independent third party laboratories. The test results are listed below:

TABLE 1

| | Test | | Functional | Color | |
|---|---|---|---|---|---|
| Test | Method | Specification | Performance | Change | Cracking |
| Humidity | UL 8750 | Section 8.12 | PASS | NO | NO |
| Exposure | | | | | |
| Dielectric 1 | UL 8750 | Section 8.12 | PASS | NO | NO |
| Corrosion | UL 50E | Section 8.7 | PASS | NO | NO |
| Test/Salt | | | | | |
| Spray | | | | | |
| Water | IEC 60529 | Section 14.2.7 | PASS | NO | NO |
| Immersion | | | | | |
| (IP-68) | | | | | |
| Thermal | Non Standard | Customer | PASS | YES | NO |
| Shock | | Specified | | | |
| Lumen Loss | | | 6-7% | | |
| CRI (Color | | | 72 | 74 | |
| Rendering Index) | | | | | |
| CCT | | | 4200 K | 4600 K | |
| (Correlated Color | | | | | |
| Temperature) | | | | | |

All test results indicate that the coating is stable to Humidity Exposure and Corrosion and Salt Spray. It has also been shown that the silicone coated LEDs pass IP-68 testing. While CRI and CCT show an improvement and are well controlled, the average lumen loss is 6-7%.

TABLE 2
Test Equipment:

| Equipment Used | Model Number | Control Number |
|---|---|---|
| Envirotronics | SSH32-c | H190 |
| Thermotron | SM-32C | H147 |
| Despatch | LAC1-67 | H138 |
| Omega | 650-TF-DDS | T036 |
| Singleton Corp | SCCH22 | H168 |
| Atago Co | ES-421 | M185 |
| Oakton | WD-25624-86 | I027 |
| Pyrex | 3062-100 | B046 |
| Biddle | 230425 | V178S |
| Fisher Scientific | 14-649-9 | N1132 |
| Fluke | 87V | M207 |
| Stanley | 33-428 | U011 |
| Water Tank | N/A | N/A |

TABLE 3
LED Sample Boards:

| Sample Number | Description | Model Number |
|---|---|---|
| 203303-1 | PCB 6 LED'S | CREE 5 |
| 203303-2 | PCB 102 LED'S | Sylvania 102-2 |
| 203303-3 | PCB 4 LED'S | Philips 1 |
| 203303-4 | PCB 6 LED'S | CREE 4 |
| 203303-5 | PCB 102 LED'S | Sylvania 102-3 |
| 203303-6 | PCB 4 LED'S | Philips 3 |
| 203303-7 | PCB 6 LED'S | CREE 6 |
| 203303-8 | PCB 54 LED'S | Sylvania 54-3 |
| 203303-9 | PCB 4 LED'S | Philips 4 |
| 203303-10 | PCB 6 LED'S | CREE 7 |
| 203303-11 | PCB 54 LED'S | Sylvania 54-5 |
| 203303-12 | PCB 4 LED'S | Philips 2 |
| 203303-13 | PCB 102 LED'S | Sylvania 102-5 |

The following tests were conducted to determine the functionality and lumen performance of the silicone coated LEDs. All testing was conducted by third party independent laboratories. Intertek, which is located in Cortland, N.Y., conducted the Environmental and Electrical testing. ITL, located in Boulder, Colo., conducted the lumen maintenance testing.

Intertek performed the following tests:

TABLE 4

| | | |
|---|---|---|
| Humidity Exposure | UL 8750 | Section 8.12 |
| Corrosion Test/Salt Spray | UL 50E | Section 8.7 |
| Water Immersion | IEC 60529 | Section 14.2.7 |
| Thermal Shock | Non Standard | Customer Specified |

Humidity Exposure UL 8750 Section 8.12:

A unit for use in damp or wet locations was exposed for 168 hours to moist air having a relative humidity of 88±2 percent at a temperature of 32.0±2.0° C. (89.6±3.6° F.). All of the samples were functional following the test. A dielectric test was performed which applied 500 Vdc for one (1) minute to test the coating on the samples. The test was conducted in a manner where the test leads were placed directly on the PCB's coating. All the samples were functional following the test. A visual check was also performed. The coating of the sample had not deteriorated and there was no change to the color or cracking.

Corrosion Test/Salt Spray UL 50E Section 8.7:

Test samples were subjected to corrosion test at the atmosphere described below for 24 hours and then the functional tests were performed.

TABLE 5

| Salinity | pH | Fallout | Temperature |
|---|---|---|---|
| 5.5% | 6.6 | 1.4 to 1.5 ml/h | 95° F. |

Following the functional tests, the samples were subjected to 144 hours of corrosion testing at the atmosphere described below and then function tests were performed.

TABLE 6

| Salinity | pH | Fallout | Temperature |
|---|---|---|---|
| 5.5% | 6.6 | 1.4 to 1.5 ml/h | 95° F. |

All samples were functional following the test. A visual check was performed. The coating of the sample had not deteriorated and there was no change of color or cracking.

Water Immersion IEC 60529 Section 14.2.7:

Samples were completely immersed in water to a level between 850 mm and 1000 mm for thirty minutes. Following the test, functional tests were performed. All samples were functional following the test. A visual check was performed. The coating of the sample had not deteriorated and there was no change of color or cracking.

Thermal Shock, Non-Standard, Customer Specified:

Samples should perform after rapidly changing temperatures from −40° C. to 150° C. Samples were subjected to five cycles. One cycle consisted of one (1) hour at 150° C. then one (1) hour at −40° C. with a transfer rate of less than one (1) minute. All samples were functional following the test. A visual, check was performed. The coating of the sample had not deteriorated and there was change of color from clear to a tan color on all samples. There was no cracking of the coatings.

It will therefore be readily understood by those persons skilled in the art that the present invention is susceptible of broad utility and application. Many embodiments and adaptations of the present invention other than those herein described, as well as many variations, modifications and equivalent arrangements, will be apparent from or reasonably suggested by the present invention and the foregoing description thereof, without departing from the substance or scope of the present invention. Accordingly, while the present invention has been described herein in detail in relation to its preferred embodiment, it is to be understood that this disclosure is only illustrative and exemplary of the present invention and is made merely for purposes of providing a full and enabling disclosure of the invention. The foregoing disclosure is not intended or to be construed to limit the present invention or otherwise to exclude any such other embodiments, adaptations, variations, modifications and equivalent arrangements.

What is claimed is:

1. A method of making a coated light-emitting diode, the method comprising:
providing a light-emitting diode having a surface, and
spray coating the surface of the light-emitting diode with a liquid coating composition comprising silicone.

2. The method according to claim 1, wherein the spray coating conforms to the surface of the light-emitting diode.

3. The method according to claim 1, wherein the coating is sprayed on a portion of the surface of the light-emitting diode or on the entire surface of the light-emitting diode.

4. The method according to claim 1, wherein the coating composition comprises at least 60 weight % silicone.

5. The method according to claim 4, wherein the coating composition comprises at least 99 weight % silicone.

6. The method according to claim 4, wherein the coating composition further comprises from 0 to 40 weight % of diisopropoxy di(ethoxyacetoacetyl) titanate, alkoxysilane reaction product, methyl alcohol, or a combination thereof.

7. The method according to claim 5, wherein the coating composition further comprises from 0 to 40 weight % of diisopropoxy di(ethoxyacetoacetyl) titanate, alkoxysilane reaction product, methyl alcohol, or a combination thereof.

8. The method according to claim 1, further comprising curing the silicone coated light-emitting diode.

9. The method according to claim 8, wherein curing is with radiant heat.

10. The method according to claim 8, wherein the curing is in a forced air oven.

11. The method according to claim 1, wherein the coating is transparent.

12. The method according to claim 1, further comprising spraying the coating with an air-assisted airless system or a bead and air swirl system.

13. A light-emitting diode having a coated surface, wherein the coating of the coated light-emitting diode comprises silicone.

14. The light-emitting diode according to claim 13, wherein the coating is sprayed-on the surface of the light-emitting diode.

15. The light-emitting diode according to claim 14, wherein the coating is applied as a liquid.

16. The light-emitting diode according to claim 13, wherein the silicone coating comprises at least 60 weight % silicone.

17. The light-emitting diode according to claim 16, wherein the silicone coating comprises at least 99 weight % silicone.

18. The light-emitting diode according to claim 16, wherein the silicone coating further comprises from 0 to 40 weight % of diisopropoxy di(ethoxyacetoacetyl) titanate, alkoxysilane reaction product, methyl alcohol, or a combination thereof.

19. The light-emitting diode according to claim 17, wherein the silicone coating further comprises from 0 to 40 weight % of diisopropoxy di(ethoxyacetoacetyl) titanate, alkoxysilane reaction product, methyl alcohol, or a combination thereof.

20. The light-emitting diode according to claim 13, wherein the spray coated light-emitting diode is cured.

21. The light-emitting diode according to claim 20, wherein the coated light-emitting diode is radiant heat cured.

22. The light-emitting diode according to claim 20, wherein the curing occurs in a forced air oven.

23. The light-emitting diode according to claim 13, wherein the silicone coating is transparent.

24. The light-emitting diode to claim 14, wherein the spray coating is applied with an air-assisted airless system or bead and air swirl system.

25. The light-emitting diode according to claim 13, wherein the silicone coating conforms to the surface of the light-emitting diode.

26. The light-emitting diode according to claim 13, wherein the coating is sprayed on a portion of the surface of the light-emitting diode or on the entire surface of the light-emitting diode.
